(19) United States
(12) Patent Application Publication
(10) Pub. No.: US 2024/0201336 A1
(43) Pub. Date: Jun. 20, 2024

(54) WAVELENGTH CONTROL SYSTEM FOR TUNABLE LASER DIODE AND LiDAR DEVICE

(71) Applicant: Samsung Electronics Co., Ltd., Suwon-si (KR)

(72) Inventors: Changbum LEE, Suwon-si (KR); Woosung Kim, Suwon-si (KR); Changgyun Shin, Suwon-si (KR)

(73) Assignee: Samsung Electronics Co., Ltd., Suwon-si (KR)

(21) Appl. No.: 18/215,419

(22) Filed: Jun. 28, 2023

(30) Foreign Application Priority Data
Dec. 14, 2022 (KR) 10-2022-0174949

(51) Int. Cl. G01S 7/481

(52) U.S. Cl. CPC G01S 7/4814; G01S 17/931

(57) ABSTRACT

Provided is a wavelength control system including a wavelength tunable laser diode including at least one optical amplifier, and a processor configured to control a tunable wavelength range of the wavelength tunable laser diode by adjusting a bias current applied to the at least one optical amplifier.

### CROSS-REFERENCE TO RELATED APPLICATION

This application is based on and claims priority under 35 U.S.C. § 119 to Korean Patent Application No. 10-2022-0174949, filed on Dec. 14, 2022, in the Korean Intellectual Property Office, the disclosure of which is incorporated by reference herein in its entirety.

### BACKGROUND

### 1. Field

Example embodiments of the disclosure relate to a wavelength control system for a wavelength tunable laser diode and a light detection and ranging (LiDAR) device.

### 2. Description of Related Art

Recently, advanced driving assistance systems (ADAS) having various functions have been commercialized. For example, there has been an increased number of vehicles equipped with functions such as adaptive cruise control (ACC), which reduces the speed of a vehicle if there is a risk of collision and the vehicle is driven within a set speed range if there is no risk of collision by recognizing a location and speed of another vehicle, and autonomous emergency braking system (AEB), which automatically applies braking to prevent collisions when there is a risk of collision by recognizing another vehicle in front of the vehicle and the driver does not respond to the risk or the response method is inappropriate. In addition, it is expected that automobiles capable of autonomous driving will be commercialized in the near future.

Accordingly, the importance of a vehicle radar that provides information about a vehicle's surroundings is gradually increasing. For example, light detection and ranging (LiDAR) devices that measure a distance, speed, azimuth, and position of an object from the time when a laser scattered or reflected returns, changes in the intensity of the laser, changes in the frequency of the laser, and changes in the polarization state of the laser are widely used as vehicle radars.

### SUMMARY

One or more example embodiments provide a wavelength control system for a tunable laser diode and a LiDAR device.

Additional aspects will be set forth in part in the description which follows and, in part, will be apparent from the description, or may be learned by practice of example embodiments.

According to an aspect of an example embodiment, there is provided a wavelength control system including a wavelength tunable laser diode including at least one optical amplifier, and a processor configured to control a tunable wavelength range of the wavelength tunable laser diode by adjusting a bias current applied to the at least one optical amplifier.

The processor may include a micro-processor.

The at least one optical amplifier may be a semiconductor optical amplifier (SOA).

A center wavelength of a gain band of the at least one optical amplifier may increase based on the bias current applied to the at least one optical amplifier increasing.

A center wavelength of a gain band of the at least one optical amplifier may decrease based on the bias current applied to the at least one optical amplifier decreasing.

The wavelength tunable laser diode may include a plurality of ring resonators, and lengths of the plurality of ring resonators may be different from each other.

The wavelength control system may further include at least one heater spaced apart from each of the plurality of ring resonators, wherein the processor may be further configured to control the tunable wavelength range of the wavelength tunable laser diode by adjusting a voltage input to the at least one heater.

The wavelength control system may further include a monitor configured to detect an output wavelength of light output from the wavelength tunable laser diode, wherein the processor may be further configured to control the bias current and a voltage input to the at least on heater by comparing a target wavelength, which is a wavelength of light targeted by the wavelength tunable laser diode, with the output wavelength.

According to another aspect of an example embodiment, there is provided a light detection and ranging (LiDAR) device including a wavelength tunable laser diode including at least one optical amplifier, a processor configured to control a tunable wavelength range of the wavelength tunable laser diode by adjusting a bias current applied to the at least one optical amplifier, an optical transmitter configured to emit light generated by the wavelength tunable laser diode external to the LiDAR device, an optical receiver configured to receive light externally, and an optical detector configured to detect light received by the optical receiver.

The processor may include a micro-processor.

The at least one optical amplifier may be a semiconductor optical amplifier (SOA).

A center wavelength of a gain band of the at least one optical amplifier may increase based on the bias current applied to the at least one optical amplifier increasing.

A center wavelength of a gain band of the at least one optical amplifier may decrease based on the bias current applied to the at least one optical amplifier decreasing.

The LiDAR device may further include at least one heater, wherein the processor may be further configured to control the tunable wavelength range of the wavelength tunable laser diode by adjusting a voltage input to the at least one heater.

The LiDAR device may further include a monitor configured to detect an output wavelength that is a wavelength of light output from the wavelength tunable laser diode, wherein the processor may be further configured to control the bias current and the voltage input to the at least on heater by comparing a target wavelength, which is a wavelength of light targeted by the wavelength tunable laser diode, with the output wavelength.

According to yet another aspect of an example embodiment, there is provided an electronic device including a light detection and ranging (LiDAR) device including a wavelength tunable laser diode including at least one optical amplifier, a processor configured to control a tunable wavelength range of the wavelength tunable laser diode by adjusting a bias current applied to the at least one optical amplifier, an optical transmitter configured to emit light generated by the wavelength tunable laser diode external to the LiDAR device, an optical receiver configured to receive light externally, and an optical detector configured to detect light received by the optical receiver.

The at least one optical amplifier may be a semiconductor optical amplifier (SOA).

A center wavelength of a gain band of the at least one optical amplifier may increase based on the bias current applied to the at least one optical amplifier increasing.

A center wavelength of a gain band of the at least one optical amplifier may decrease based on the bias current applied to the at least one optical amplifier decreasing.

The LiDAR device may further include at least one heater, wherein the processor may be further configured to control the tunable wavelength range of the wavelength tunable laser diode based on adjusting a voltage input to the at least one heater.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 illustrates a configuration of a wavelength tunable laser diode;

FIG. 2 is a block diagram of a wavelength control system according to an example embodiment;

FIG. 3 is a block diagram showing a configuration of a light detection and ranging (LiDAR) device according to an example embodiment;

FIG. 4 is a perspective view illustrating an optical transmitter configured as an optical integrated circuit on a substrate;

FIG. 5 is a block diagram showing a configuration of an electronic apparatus including a LiDAR device according to an example embodiment; and

FIG. 6 is a diagram illustrating an example embodiment in which a LiDAR device is applied to a vehicle.

### DETAILED DESCRIPTION

Reference will now be made in detail to embodiments, examples of which are illustrated in the accompanying drawings, wherein like reference numerals refer to like elements throughout. In this regard, example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, a wavelength control system for a tunable laser diode and a light detection and ranging (LiDAR) device will be described in detail with reference to the accompanying drawings. In the drawings, like reference numerals denote like elements and sizes of constituent elements may be exaggerated for convenience of explanation and clarity. The embodiments of the disclosure are capable of various modifications and may be embodied in many different forms.

It will be understood that when an element or layer is referred to as being “on” or “above” another element or layer, the element or layer may be directly on another element or layer or intervening elements or layers. Singular forms are intended to include the plural forms as well, unless the context clearly indicates otherwise. It should be understood that, when a part “comprises” or “includes” an element in the specification, unless otherwise defined, it is not excluding other elements but may further include other elements.

In the specification, the term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Connections or connection members of lines between components shown in the drawings illustrate functional connections and/or physical or circuit connections, and the connections or connection members can be represented by replaceable or additional various functional connections, physical connections, or circuit connections in an actual apparatus.

The use of any and all examples, or exemplary language provided herein, is intended merely to better illuminate the disclosure and does not pose a limitation on the scope of the disclosure unless otherwise claimed.

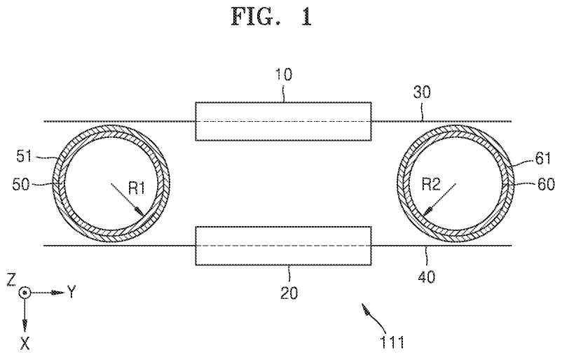

FIG. 1 is a diagram showing a configuration of a wavelength tunable laser diode 111.

Referring to FIG. 1, the wavelength tunable laser diode 111 may include a first optical waveguide 30 and a second optical waveguide 40 arranged parallel to each other, a first optical amplifier 10 provided on the first optical waveguide 30, a second optical amplifier 20 provided on the second optical waveguide 40, a first ring resonator 50 and a second ring resonator 60 provided between the first optical waveguide 30 and the second optical waveguide 40, and a first heater 51 and a second heater 61. For example, the wavelength tunable laser diode 111 may be an on-chip type wavelength tunable laser in which all components are integrated on a single substrate.

The first optical waveguide 30 and the second optical waveguide 40 may be disposed facing each other at a distance from each other in a first direction (i.e., an X-axis direction) on the substrate. In addition, each of the first optical waveguide 30 and the second optical waveguide 40 may extend in a second direction (i.e., a Y-axis direction) perpendicular to the first direction.

The first optical amplifier 10 and the second optical amplifier 20 may be semiconductor optical amplifiers (SOA) integrated on a substrate using a semiconductor process. The first optical amplifier 10 and the second optical amplifier 20 may amplify light and simultaneously generate light. For example, the first optical amplifier 10 may be configured to generate light and provide light to the first optical waveguide 30 and, at the same time, to amplify light traveling along the first optical waveguide 30. Also, the second optical amplifier 20 may be configured to generate light and provide the light to the second optical waveguide 40 and, at the same time, to amplify light traveling along the second optical waveguide 40. The first optical amplifier 10 on the first optical waveguide 30 and the second optical amplifier 20 on the second optical waveguide 40 are spaced apart from each other in the first direction and may extend along the second direction.

The first ring resonator 50 and the second ring resonator 60 are disposed between the first optical waveguide 30 and the second optical waveguide 40 in the first direction, and may be disposed so that the first optical amplifier 10 and the second optical amplifier 20 are interposed therebetween in the second direction. For example, the first ring resonator 50 may be disposed between the first optical waveguide 30 and the second optical waveguide 40 in the first direction near a first end unit of the first optical amplifier 10 and a first end unit of the second optical amplifier 20 in the second direction. In addition, the second ring resonator 60 may be disposed between the first optical waveguide 30 and the second optical waveguide 40 in the first direction near a second end unit of the first optical amplifier 10 and a second end unit of the second optical amplifier 20 opposite to the first end unit in the second direction. In FIG. 1, although it is depicted that the wavelength tunable laser diode 111 includes two ring resonators, embodiments are not limited thereto, and the wavelength tunable laser diode 111 may include three or more ring resonators as needed. Hereinafter, for convenience, a case in which the wavelength tunable laser diode 111 includes two ring resonators as an example will be described.

The first ring resonator 50 and the second ring resonator 60 do not physically contact the first optical waveguide 30 and the second optical waveguide 40, but may be disposed to be optically coupled to each other. The shortest distance between the first optical waveguide 30 and the first ring resonator 50, the shortest distance between the first optical waveguide 30 and the second ring resonator 60, the shortest distance between the second optical waveguide 40 and the first ring resonator 50, and the shortest distance between the second optical waveguide 40 and the second ring resonator 60 may be less than or equal to about twice a width of the first and second optical waveguides 30 and 40, for example, in a range from about 0.5 times to about 1 times the width of the first and second optical waveguides 30 and 40. For example, the shortest distance between the first optical waveguide 30 and the first ring resonator 50, the shortest distance between the first optical waveguide 30 and the second ring resonator 60, the shortest distance between the second optical waveguide 40 and the first ring resonator 50, and the shortest distance between the second optical waveguide 40 and the second ring resonator 60 may be in a range from about 0.1 μm or to about 1 μm, but embodiments are not limited thereto. Then, light traveling along the first optical waveguide 30 or the second optical waveguide 40 may be transferred to the first ring resonator 50 or the second ring resonator 60, and a part of light resonating in the first ring resonator 50 or the second ring resonator 60 may be transmitted to the first optical waveguide 30 or the second optical waveguide 40.

The first ring resonator 50 and the second ring resonator 60 are closed-loop resonators having ring-shaped waveguides. Wavelengths of light resonating in the first ring resonator 50 and the second ring resonator 60 may vary depending on diameters of the first ring resonator 50 and the second ring resonator 60 or circumferential lengths of the ring-shaped waveguide. For example, the resonance wavelengths of the first ring resonator 50 and the second ring resonator 60 may vary depending on the diameters of the first ring resonator 50 and the second ring resonator 60 or the circumferential lengths of the ring-shaped waveguide. A diameter R1 of the first ring resonator 50 and a diameter R2 of the second ring resonator 60 may be the same or different. For example, the resonant wavelength of the first ring resonator 50 and the resonant wavelength of the second ring resonator 60 may be the same or different.

The first and second heaters 51 and 61 may be respectively disposed on outer circumferences of the first ring resonator 50 and the second ring resonator 60. The first and second heaters 51 and 61 may be doped with an impurity at a relatively high concentration, and heat may be generated when a voltage is applied to both ends of the first and second heaters 51 and 61. Accordingly, a wavelength of light may be changed by applying heat to the light input to the first and second ring resonators 50 and 60. The first and second heaters 51 and 61 may be regions doped with impurities at a concentration in a range of about 10¹⁸/cm³ to about 10¹⁹/cm³. In FIG. 1, it is depicted that the first and second heaters 51 and 61 are disposed around the outer circumferences of the first ring resonator 50 and the second ring resonator 60, but embodiments are not limited thereto. In addition, in FIG. 1, although shown as including two heaters as an example, embodiments are not necessarily limited thereto.

In addition, the resonance wavelength of the first ring resonator 50 and the resonance wavelength of the second ring resonator 60 may be finely adjusted by a controller 112. For example, the controller 112 may change a phase of light traveling along the first and second ring resonators 50 and 60, respectively. When the phase of light changes, an effect of changing an optical length of a closed-curve waveguide occurs, and thus, the resonant wavelengths of the first and second ring resonators 50 and 60 change. For example, when a phase delay of light increases, the optical length of the closed-curve waveguide increases, and thus, the resonant wavelengths of the first and second ring resonators 50 and 60 may be increased. Conversely, when a phase delay of light decreases, the optical length of the closed-curve waveguide shortens, and thus, the resonant wavelengths of the first and second ring resonators 50 and 60 may be reduced.

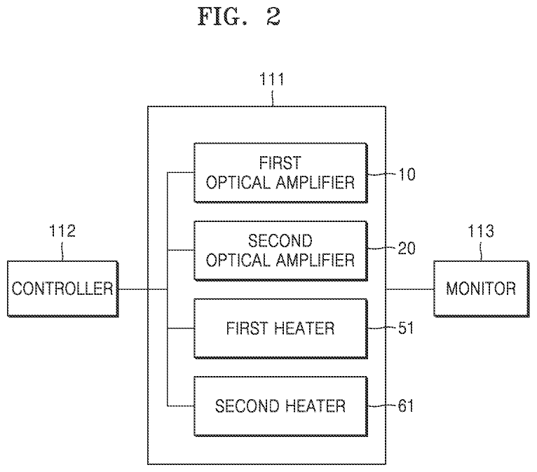

FIG. 2 is a schematic block diagram of a wavelength control system according to an embodiment.

Referring to FIG. 2, the wavelength control system may include the wavelength tunable laser diode 111, a controller 112, and a monitor 113. The wavelength tunable laser diode 111 may include the first optical amplifier 10, the second optical amplifier 20, the first heater 51, and the second heater 61. The controller 112 may be connected to the first optical amplifier 10, the second optical amplifier 20, the first heater 51, the second heater 61, and the monitor 113 included in the wavelength tunable laser diode 111 through conductive lines. The controller 112 may drive the first optical amplifier 10, the second optical amplifier 20, the first heater 51 and the second heater 61, and the monitor 113. The controller 112 may inject a bias current (or a voltage) to the first optical amplifier 10 and the second optical amplifier 20, respectively. According to the bias current applied to the first optical amplifier 10 and the second optical amplifier 20, respectively, a gain band, which is a wavelength band in which the first optical amplifier 10 and the second optical amplifier 20 may obtain a certain gain or more may be changed. The controller 112 may control gain bands of the first and second optical amplifiers 10 and 20 by increasing or decreasing bias currents of the first and second optical amplifiers 10 and 20. For example, the controller 112 may increase the bias current applied to the first optical amplifier 10 or the second optical amplifier 20 in a long wavelength region, and may reduce the bias current applied to the first optical amplifier 10 or the second optical amplifier 20 in a short wavelength region. When the bias current of the first optical amplifier 10 or the second optical amplifier 20 increases, a center wavelength of a gain band may increase, and when the bias current of the first optical amplifier 10 or the second optical amplifier 20 decreases, the center wavelength of the gain band may decrease. Accordingly, the controller 112 may increase a gain bandwidth of the first optical amplifier 10 and the second optical amplifier 20 and a tunable wavelength range of the wavelength tunable laser diode 111 by controlling the bias current applied to the first optical amplifier 10 or the second optical amplifier 20 of the wavelength tunable laser diode 111.

In addition, the controller 112 may control the tunable wavelength range by changing a temperature of the first and second ring resonators 50 and 60 or by changing a concentration of carriers (e.g., electrons or holes). For example, by changing the temperatures of the first and second ring resonators 50 and 60, the refractive indices of the first and second ring resonators 50 and 60 may be changed, and resonance wavelengths of the first and second ring resonators 50 and 60 may be controlled. In addition, the controller 112 may adjust a tunable wavelength range by changing a gain profile by changing a temperature around the first and second optical amplifiers 10 and 20. For example, the controller 112 may change a temperature around the first and second ring resonators 50 and 60 by adjusting voltages applied to the first heater 51 and the second heater 61. In addition, by changing the carrier concentration by locating a diode junction around the center of the first and second ring resonators 50 and 60, refractive indices of the first and second ring resonators 50 and 60 may be changed, and resonance wavelengths of the first and second ring resonators 50 and 60 may be controlled.

The controller 112 may control resonance wavelengths of the first and second ring resonators 50 and 60 and control gain bands of the first and second optical amplifiers 10 and 20. Light output from the wavelength tunable laser diode 111 may satisfy both the resonance condition of the first ring resonator 50 and the resonance condition of the second ring resonators 60, and may have a wavelength within a gain band of the first and second optical amplifiers 10 and 20. Accordingly, a wavelength of light output from the wavelength tunable laser diode 111 may be controlled by controlling the controller 112.

The controller 112 may include a processor that may be physically implemented by analog and/or digital circuits including one or more of a logic gate, an integrated circuit, a microprocessor, a microcontroller, a memory circuit, a passive electronic component, an active electronic component, an optical component, and the like, and may be driven by firmware and software configured to perform the functions or operations described herein.

The monitor 113 may detect an output wavelength that is a wavelength of light output from the wavelength tunable laser diode 111. A bias current may be controlled by comparing the output wavelength detected by the monitor 113 with a target wavelength, which is a wavelength of light targeted by the wavelength tunable laser diode 111.

Although one controller 112 may be provided for the first and second ring resonators 50 and 60, a plurality of controllers 112 may be provided for each of the first and second ring resonators 50 and 60. FIG. 2 shows that one controller 112 is illustratively provided for the first ring resonator 50, the second ring resonator 60, the first heater 51, and the second heater 61, but the number of controllers 112 is not limited thereto. In addition, although one wavelength tunable laser diode 111 is illustrated as being provided with respect to the controller 112, the number of the wavelength tunable laser diode 111 is not limited thereto. One controller 112 may be provided for the plurality of wavelength tunable laser diodes 111.

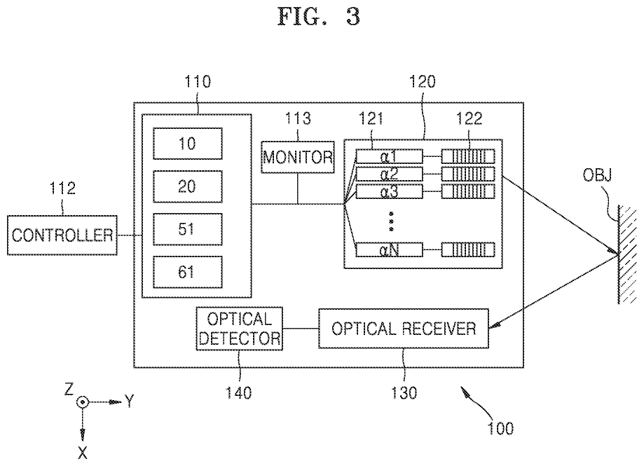

FIG. 3 is a block diagram showing a configuration of a LiDAR device 100 according to an example embodiment.

Referring to FIG. 3, the LiDAR device 100 according to the example embodiment may include a wavelength tunable laser diode 111, a controller 112, a monitor 113, an optical transmitter 120 configured to emit light generated from the wavelength tunable laser diode 111 to the outside of the LiDAR device 100, an optical receiver 130 configured to receive external light coming from the outside of the LIDAR device 100, and an optical detector 140 configured to detect light received by the optical receiver 130. The optical detector 140 may be a photodetector. The wavelength tunable laser diode 111 of FIG. 3 may include a wavelength tunable laser diode 111 including a first optical amplifier 10, a second optical amplifier 20, a first heater 51, and a second heater 61 as in FIG. 2.

The controller 112 included in the LIDAR device 100 may increase gain bandwidths of the first optical amplifier 10 and the second optical amplifier 20 and increase a tunable wavelength range of the wavelength tunable laser diode 111 by controlling a bias current applied to the first optical amplifier 10 or the second optical amplifier 20 of the wavelength tunable laser diode 111. Accordingly, the output power of a laser beam output from the LiDAR device 100 may be increased, and a viewing angle of the LiDAR device 100 may be increased.

In FIG. 3, it is illustrated as including only one wavelength tunable laser diode as an example, but embodiments are not necessarily limited thereto. For example, the LIDAR device 100 may include a plurality of wavelength tunable laser diodes 111. The plurality of wavelength tunable laser diodes 111 may emit light of different wavelength bands. For example, the LiDAR device 100 may include a first wavelength tunable laser diode emitting light of a first wavelength band λ1, a second wavelength tunable laser diode emitting light of a second wavelength band λ2 different from the first wavelength band λ1, a third wavelength tunable laser diode emitting light of a third wavelength band λ3 different from the first and second wavelength bands λ1 and λ2, a fourth wavelength tunable laser diode emitting light of a fourth wavelength band λ4 different from the first to third wavelength bands λ1, λ2, and λ3, and a fifth wavelength tunable laser diode emitting light of a fifth wavelength band λ5 different from the first to fourth wavelength bands λ1, λ2, λ3, and λ4. The first wavelength tunable laser diode may be configured to emit light of any one wavelength within the first wavelength band λ1 according to electrical control. The second wavelength tunable laser diode may be configured to emit light of any one wavelength within the second wavelength band λ2 according to electrical control. The third wavelength tunable laser diode may be configured to emit light of any one wavelength within the third wavelength band λ3 according to electrical control. The fourth wavelength tunable laser diode may be configured to emit light of any one wavelength within the fourth wavelength band λ4 according to electrical control. The fifth wavelength tunable laser diode may be configured to emit light of any one wavelength within the fifth wavelength band λ5 according to electrical control. The number of wavelength tunable laser diodes may be appropriately selected in consideration of a bandwidth of the wavelength tunable laser diode, the scanning range of the LIDAR device 100, and the like. The LIDAR device 100 described above may be applied to various electronic apparatuses for detecting a distance to an external object or acquiring a three dimensional (3D) image.

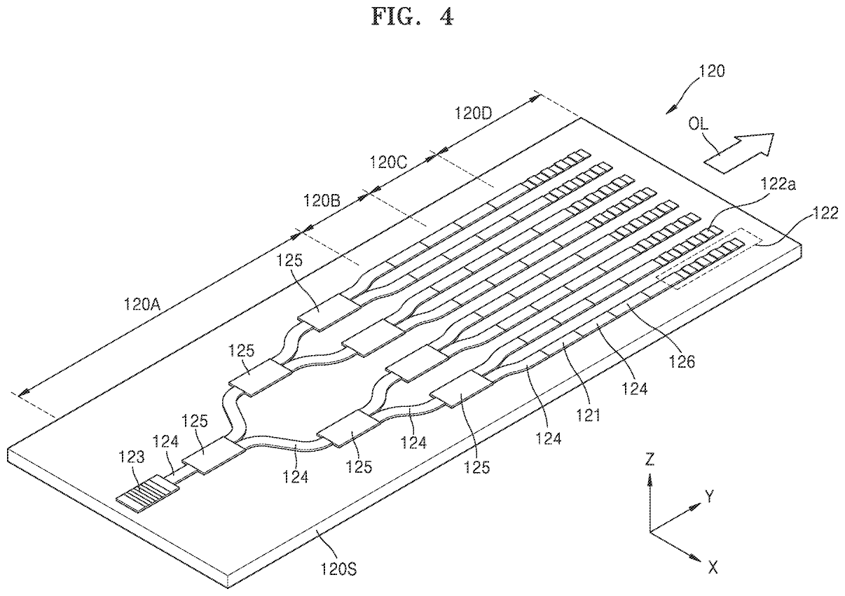

FIG. 4 is a perspective view illustrating an optical transmitter 120 configured in the form of an optical integrated circuit on a substrate. An optical phased array of the optical transmitter 120 described above may be implemented as one photonic integrated circuit (PIC) on one substrate.

Referring to FIG. 4, the optical transmitter 120 may include a substrate 120S, an input coupler 123 disposed on the substrate 120S, a branch region 120A, a phase control region 120B, an amplification region 120C, and an emission region 120D. The input coupler 123, the branch region 120A, the phase control region 120B, the amplification region 120C, and the emission region 120D may be arranged in a second direction.

The input coupler 123 may couple light from the wavelength tunable laser diode 111 to an optical path within the optical transmitter 120. In another example embodiment, the wavelength tunable laser diode 111 may be integrally disposed on the substrate 120S of the optical transmitter 120. In this case, the wavelength tunable laser diode 111 may be disposed at the position of the input coupler 123, and the input coupler 123 may be omitted.

The optical transmitter 120 may include a plurality of optical waveguides 124 that sequentially transmit light generated from the light source 110 to the branch region 120A, the phase control region 120B, the amplification region 120C, and the emission region 120D. Light generated from the wavelength tunable laser diode 111 may travel in the second direction through the optical waveguide 124.

The branch region 120A may include a plurality of light distributors 125. The plurality of light distributors 125 may divide one light traveling along the optical waveguide 124 into several pieces of light. To this end, one optical waveguide 124 may be connected to an input end of each light distributor 125 and a plurality of optical waveguides 124 may be connected to an output end of each light distributor 125. As an example, a plurality of light distributors 125 that each distributes one light beam into two light beams are shown in FIG. 4. Light may be divided into a plurality of pieces of light beams in the branch region 120A. The plurality of divided pieces of light beams respectively travel along the plurality of optical waveguides 124. Although it is shown in FIG. 4 that the light is divided into 8 pieces of light in the branch region 120A, this is an example and embodiments are not necessarily limited thereto.

The phase control region 120B may include a plurality of optical modulators 121 respectively disposed on the plurality of optical waveguides 124. For example, the plurality of light modulators 121 may be arranged in the first direction perpendicular to the second direction. A plurality of pieces of light divided in the branch region 120A may be respectively provided to the plurality of optical modulators 121. The light modulator 121 may have a variable refractive index that is electrically controlled. Phases of light passing through the light modulator 121 may be determined according to the refractive index of the light modulator 121. The optical modulator 121 may independently control phases of the divided pieces of light beams.

The amplification region 120C may include a plurality of optical amplifiers 126 respectively disposed in the plurality of optical waveguides 124. The plurality of optical amplifiers 126 may be arranged in the first direction perpendicular to the second direction. The optical amplifier 126 may increase the magnitude of an optical signal. For example, the optical amplifier 126 may include a SOA or ion doped amplifier.

The emission region 120D may include a plurality of grating antennas 122. The plurality of grating antennas 122 may be arranged in the first direction. The plurality of grating antennas 122 may be respectively connected to the plurality of optical amplifiers 126. Each grating antenna 122 may emit light amplified in the amplification region 120C. To this end, each of the grating antennas 122 may include a plurality of grating patterns 122a that are periodically arranged. The plurality of grating patterns 122a may be arranged in the second direction. The traveling direction of output light OL emitted by the grating antenna 122 may be determined by a phase difference between a plurality of divided pieces of light beams determined in the phase control region 120B and a wavelength of the light provided from the wavelength tunable laser diode 111. For example, a first direction component of the output light OL (i.e., an azimuthal angle component) may be determined by a phase difference between a plurality of pieces of light, and a third direction component (i.e., an elevation angle component) of the output light OL may be determined by a wavelength of light.

Although FIG. 4 shows an example in which only the optical transmitter 120 is implemented as a single optical integrated circuit. However, components of the LIDAR device 100 including the wavelength tunable laser diode 111, the controller 112, the monitor 113, the optical transmitter 120, the optical receiver 130, and the optical detector 140 may be implemented together as one optical integrated circuit.

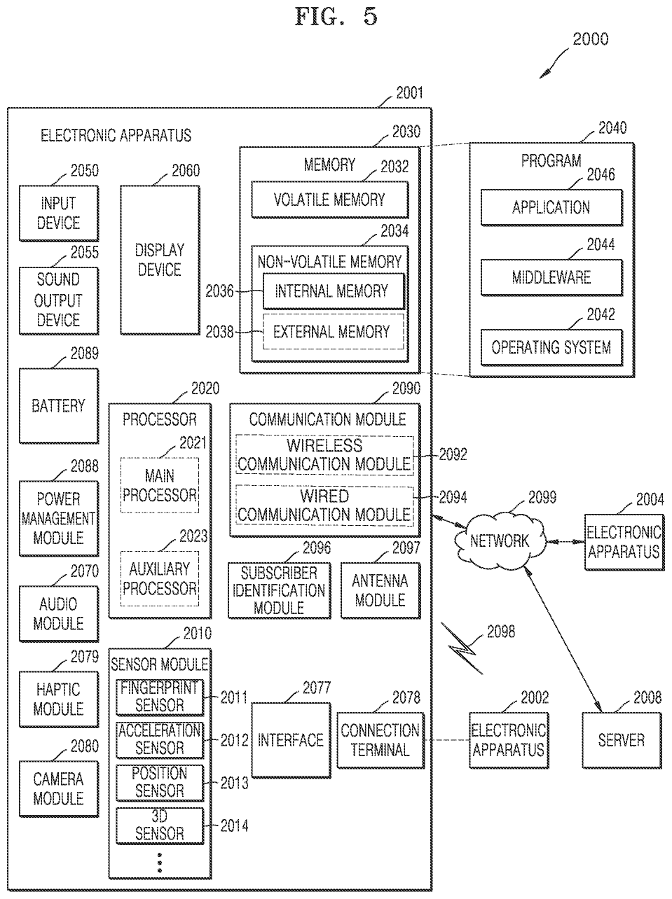

FIG. 5 is a block diagram showing a configuration of an electronic apparatus 2001 including a LiDAR device according to an example embodiment.

Referring to FIG. 5, in a network environment 2000, an electronic apparatus 2001 may communicate with other electronic apparatus 2002 through a first network 2098 (a short-distance wireless communication network, etc.) or communicate with another electronic apparatus 2004 and/or server 2008 via a second network 2099 (a long-distance wireless communication network, etc.). The electronic apparatus 2001 may communicate with the electronic apparatus 2004 through the server 2008. The electronic apparatus 2001 may include a processor 2020, a memory 2030, an input device 2050, an audio output device 2055, a display device 2060, an audio module 2070, a sensor module 2010, an interface 2077, a haptic module 2079, a camera module 2080, a power management module 2088, a battery 2089, a communication module 2090, a subscriber identification module 2096, and/or an antenna module 2097. In the electronic apparatus 2001, some of these components (such as the display device 2060) may be omitted or other components may be added. Some of these components may be implemented as a single integrated circuit. For example, a fingerprint sensor 2011 of the sensor module 2010, an iris sensor, or an illumination sensor may be implemented by being embedded in the display device 2060 (a display, etc.).

The processor 2020 may control one or a plurality of other components (hardware, software components, etc.) of the electronic apparatus 2001 connected to the processor 2020 by executing software (a program 2040, etc.), and may perform various data processing or calculations. As a part of data processing or calculations, the processor 2020 may load commands and/or data received from other components (the sensor module 2010, the communication module 2090, etc.) into a volatile memory 2032 and process the commands and/or data stored in the volatile memory 2032, and resulting data may be stored in a non-volatile memory 2034. The processor 2020 may include a main processor 2021 (central processing unit, application processor, etc.) and an auxiliary processor 2023 (graphics processing unit, image signal processor, sensor hub processor, communication processor, etc.) that may be operated independently or together with the main processor 2021. The auxiliary processor 2023 may use less power than the main processor 2021 and perform specialized functions.

The auxiliary processor 2023 may control functions and/or states related to some of the components (the display device 2060, the sensor module 2010, the communication module 2090, etc.) of the electronic apparatus 2001 in place of the main processor 2021 while the main processor 2021 is in an inactive state (a sleep state) or together with the main processor 2021 while the main processor 2021 is in an active state (an application execution state). The auxiliary processor 2023 (an image signal processor, a communication processor, etc.) may be implemented as a part of other functionally related components (the camera module 2080, the communication module 2090, etc.).

The memory 2030 may store various data required by the components (the processor 2020, the sensor module 2010, etc.) of the electronic apparatus 2001. Data may include, for example, input data and/or output data for software (the program 2040, etc.) and instructions related to the software. The memory 2030 may include a volatile memory 2032 and/or a non-volatile memory 2034.

The program 2040 may be stored as software in the memory 2030 and may include an operating system 2042, middleware 2044, and/or applications 2046.

The input device 2050 may receive commands and/or data to be used for a component (the processor 2020, etc.) of the electronic apparatus 2001 from the outside of the electronic apparatus 2001 (a user, etc.). The input device 2050 may include a microphone, mouse, keyboard, and/or digital pen (a stylus pen, etc.).

The audio output device 2055 may output sound signals to the outside of the electronic apparatus 2001. The audio output device 2055 may include a speaker and/or a receiver. The speaker may be used for general purposes, such as multimedia playback or recording playback, and the receiver may be used to receive an incoming call. The receiver may be coupled as a part of the speaker or implemented as an independent separate device.

The display device 2060 may visually provide information to the outside of the electronic apparatus 2001. The display device 2060 may include a display, a hologram device, or a projector and a control circuit for controlling the device. The display device 2060 may include a touch circuitry set to sense a touch and/or a sensor circuit (such as a pressure sensor) set to measure the strength of a force generated by a touch.

The audio module 2070 may convert sound into an electrical signal or vice versa. The audio module 2070 may obtain a sound through the input device 2050, or output a sound through a speaker and/or headphone of another electronic apparatus (such as the electronic apparatus 2002) connected directly or wirelessly to the audio output device 2055 and/or the electronic apparatus 2001.

The sensor module 2010 may detect an operation state (power, temperature, etc.) of the electronic apparatus 2001 or an external environmental state (user state, etc.), and generates an electrical signal and/or data value corresponding to the detected state. The sensor module 2010 may include a fingerprint sensor 2011, an acceleration sensor 2012, a position sensor 2013, a 3D sensor 2014, and the like, and besides above, may include an iris sensor, a gyro sensor, an air pressure sensor, a magnetic sensor, a grip sensor, a proximity sensor, a color sensor, an IR (Infrared) sensor, a biological sensor, a temperature sensor, a humidity sensor, and/or an illuminance sensor.

The 3D sensor 2014 senses a shape and movement of an object by irradiating a predetermined light onto the object and analyzing light reflected from the object, and may include the LiDAR device 100 according to an embodiment described above.

The interface 2077 may support at least one designated protocol that may be used to directly or wirelessly connect the electronic apparatus 2001 to another electronic apparatus (e.g., the electronic apparatus 2002). The interface 2077 may include a high definition multimedia interface (HDMI), a universal serial bus (USB) interface, an SD card interface, and/or an audio interface.

A connection terminal 2078 may include a connector through which the electronic apparatus 2001 may be physically connected to another electronic apparatus (such as the electronic apparatus 2002). The connection terminal 2078 may include an HDMI connector, a USB connector, an SD card connector, and/or an audio connector (such as a headphone connector).

The haptic module 2079 may convert an electrical signal into mechanical stimuli (vibration, movement, etc.) or electrical stimuli that a user may recognize through tactile or kinesthetic senses. The haptic module 2079 may include a motor, a piezoelectric element, and/or an electrical stimulation device.

The camera module 2080 may capture still images and moving images. The camera module 2080 may include a lens assembly including one or more lenses, image sensors, image signal processors, and/or flashes. The lens assembly included in the camera module 2080 may collect light emitted from an object that is an image capture target,

The power management module 2088 may manage power supplied to the electronic apparatus 2001. The power management module 388 may be implemented as a part of a Power Management Integrated Circuit (PMIC).

The battery 2089 may supply power to components of the electronic apparatus 2001. The battery 2089 may include a non-rechargeable primary cell, a rechargeable secondary cell, and/or a fuel cell.

The communication module 2090 may establish a direct (wired) communication channel and/or wireless communication channel between the electronic apparatus 2001 and other electronic apparatuses (the electronic apparatus 2002, the electronic apparatus 2004, the server 2008, etc.), and support communication through the established communication channel. The communication module 2090 may include one or more communication processors that are independently operated from the processor 2020 (application processor, etc.) and support direct communication and/or wireless communication. The communication module 2090 may include a wireless communication module 2092 (a cellular communication module, a short-range wireless communication module, a Global Navigation Satellite System (GNSS), etc.) communication module) and/or a wired communication module 2094 (a Local Area Network (LAN) communication module, a power line communication module, etc.). Among these communication modules, a corresponding communication module may communicate with other electronic apparatuses through the first network 2098 (a short-range communication network, such as Bluetooth, WiFi Direct or Infrared Data Association (IrDA)) or the second network 2099 (a telecommunication network, such as a cellular network, the Internet, or a computer network (LAN and WAN), etc.). The various types of communication modules may be integrated into one component (a single chip, etc.) or implemented as a plurality of components (plural chips) separate from each other. The wireless communication module 2092 may identify and authenticate the electronic apparatus 2001 within a communication network, such as the first network 2098 and/or the second network 2099 by using subscriber information (such as, International Mobile Subscriber Identifier (IMSI)) stored in a subscriber identification module 2096.

The antenna module 2097 may transmit or receive signals and/or power to and from the outside (other electronic apparatuses, etc.). The antenna may include a radiator having a conductive pattern formed on a substrate (PCB, etc.). The antenna module 2097 may include one or a plurality of antennas. When a plurality of antennas is included in the antenna module 2097, an antenna suitable for a communication method used in a communication network, such as the first network 2098 and/or the second network 2099 from among the plurality of antennas may be selected by the communication module 2090. Signals and/or power may be transmitted or received between the communication module 2090 and another electronic apparatus through the selected antenna. In addition to the antenna, other components (an RFIC, etc.) may be included as a part of the antenna module 2097.

Some of the components are connected to each other through a communication method between peripheral devices (a bus, a General Purpose Input and Output (GPIO), a Serial Peripheral Interface (SPI), a Mobile Industry Processor Interface (MIPI), etc.), and may interchange signals (commands, data, etc.).

Commands or data may be transmitted or received between the electronic apparatus 2001 and the external electronic apparatus 2004 through the server 2008 connected to the second network 2099. The other electronic apparatuses 2002 and 2004 may be the same or different types of electronic apparatus 2001. All or some of operations performed in the electronic apparatus 2001 may be performed in one or more of the other electronic apparatuses 2002, 2004, and 2008. For example, when the electronic apparatus 2001 needs to perform a function or service, the electronic apparatus 2001 may request one or more other electronic apparatuses to perform some or all functions or services instead of executing the functions or services itself. One or more other electronic apparatuses receiving the request may execute an additional function or service related to the request, and transmit a result of the execution to the electronic apparatus 2001. For this purpose, cloud computing, distributed computing, and/or client-server computing technologies may be used.

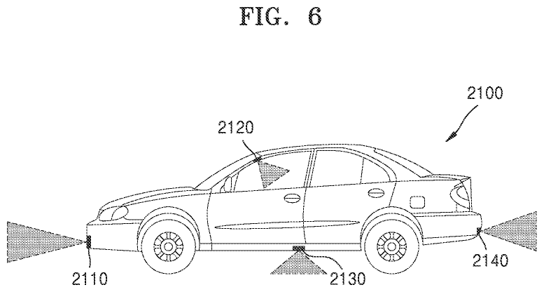

FIG. 6 is a diagram schematically showing an example in which LiDAR devices according to example embodiments are applied to a vehicle 2100.

Referring to FIG. 6, the vehicle 2100 may include a plurality of LiDAR devices 2110, 2120, 2130, and 2140 disposed in various locations. The vehicle 2100 may provide various information with respect to the surroundings of the vehicle 2100 to the driver using the plurality of LiDAR devices 2110, 2120, 2130, and 2140, and may provide information necessary for autonomous driving by automatically recognizing objects or people around the vehicle 2100. The plurality of LiDAR devices 2110, 2120, 2130, and 2140 may be the LiDAR device 100 according to an example embodiment shown in FIG. 3.

According to an example embodiment, a tunable wavelength range of a wavelength tunable laser diode may be controlled by controlling a bias current applied to an optical amplifier included in the wavelength tunable laser diode.

In addition, the output power of a laser beam output from a LiDAR device may increase, and a viewing angle of the LiDAR device may increase.

A LiDAR device having a relatively wide scanning angle range has been described with reference to the example embodiments shown in the drawings. However, it will be understood by those of ordinary skill in the art that various changes in form and details may be made therein without departing from the spirit and scope of the disclosure. Therefore, the example embodiments should be considered in descriptive sense only and not for purposes of limitation. The scope of the disclosure is defined not by the detailed description of the disclosure but by the appended claims, and all differences within the scope will be construed as being included in the disclosure.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. A wavelength control system comprising:
a wavelength tunable laser diode comprising at least one optical amplifier; and
a processor configured to control a tunable wavelength range of the wavelength tunable laser diode by adjusting a bias current applied to the at least one optical amplifier.

2. The wavelength control system of claim 1, wherein the processor comprises a micro-processor.

3. The wavelength control system of claim 1, wherein the at least one optical amplifier is a semiconductor optical amplifier (SOA).

4. The wavelength control system of claim 1, wherein a center wavelength of a gain band of the at least one optical amplifier increases based on the bias current applied to the at least one optical amplifier increasing.

5. The wavelength control system of claim 1, wherein a center wavelength of a gain band of the at least one optical amplifier decreases based on the bias current applied to the at least one optical amplifier decreasing.

6. The wavelength control system of claim 1, wherein the wavelength tunable laser diode comprises a plurality of ring resonators, and
wherein lengths of the plurality of ring resonators are different from each other.

7. The wavelength control system of claim 6, further comprising at least one heater spaced apart from each of the plurality of ring resonators,
wherein the processor is further configured to control the tunable wavelength range of the wavelength tunable laser diode by adjusting a voltage input to the at least one heater.

8. The wavelength control system of claim 6, further comprising a monitor configured to detect an output wavelength of light output from the wavelength tunable laser diode,
wherein the processor is further configured to control the bias current and a voltage input to the at least on heater by comparing a target wavelength, which is a wavelength of light targeted by the wavelength tunable laser diode, with the output wavelength.

9. A light detection and ranging (LiDAR) device comprising:
a wavelength tunable laser diode comprising at least one optical amplifier;
a processor configured to control a tunable wavelength range of the wavelength tunable laser diode based on adjusting a bias current applied to the at least one optical amplifier;
an optical transmitter configured to emit light generated by the wavelength tunable laser diode to outside of the LiDAR device;
an optical receiver configured to receive light externally; and
an optical detector configured to detect light received by the optical receiver.

10. The LiDAR device of claim 9, wherein the processor comprises a micro-processor.

11. The LiDAR device of claim 9, wherein the at least one optical amplifier is a semiconductor optical amplifier (SOA).

12. The LiDAR device of claim 9, wherein a center wavelength of a gain band of the at least one optical amplifier increases based on the bias current applied to the at least one optical amplifier increasing.

13. The LiDAR device of claim 9, wherein a center wavelength of a gain band of the at least one optical amplifier decreases based on the bias current applied to the at least one optical amplifier decreasing.

14. The LiDAR device of claim 9, further comprising at least one heater,
wherein the processor is further configured to control the tunable wavelength range of the wavelength tunable laser diode by adjusting a voltage input to the at least one heater.

15. The LiDAR device of claim 14, further comprising a monitor configured to detect an output wavelength that is a wavelength of light output from the wavelength tunable laser diode,
wherein the processor is further configured to control the bias current and the voltage input to the at least on heater by comparing a target wavelength, which is a wavelength of light targeted by the wavelength tunable laser diode, with the output wavelength.

16. An electronic device comprising:
a light detection and ranging (LiDAR) device comprising:
a wavelength tunable laser diode comprising at least one optical amplifier;
a processor configured to control a tunable wavelength range of the wavelength tunable laser diode by adjusting a bias current applied to the at least one optical amplifier;
an optical transmitter configured to emit light generated by the wavelength tunable laser diode external to the LiDAR device;
an optical receiver configured to receive light externally; and
an optical detector configured to detect light received by the optical receiver.

17. The electronic device of claim 16, wherein the at least one optical amplifier is a semiconductor optical amplifier (SOA).

18. The LiDAR device of claim 16, wherein a center wavelength of a gain band of the at least one optical amplifier increases based on the bias current applied to the at least one optical amplifier increasing.

19. The LiDAR device of claim 16, wherein a center wavelength of a gain band of the at least one optical amplifier decreases based on the bias current applied to the at least one optical amplifier decreasing.

20. The LiDAR device of claim 16, further comprising at least one heater,
wherein the processor is further configured to control the tunable wavelength range of the wavelength tunable laser diode by adjusting a voltage input to the at least one heater.
